(19) United States
(12) Patent Application Publication
(10) Pub. No.: US 2021/0005701 A1
(43) Pub. Date: Jan. 7, 2021

(54) DISPLAY DEVICE

(71) Applicant: SHARP KABUSHIKI KAISHA, Sakai City, Osaka (JP)

(72) Inventors: TAKASHI MATSUI, Sakai City, Osaka (JP); MOTOJI SHIOTA, Sakai City, Osaka (JP); TAKESHI HORIGUCHI, Sakai City, Osaka (JP)

(21) Appl. No.: 16/976,736

(22) PCT Filed: Mar. 2, 2018
(86) PCT No.: PCT/JP2018/008148

§ 371 Date: Aug. 28, 2020

(51) Int. Cl. H01L 27/32; H01L 51/00

(52) U.S. Cl. CPC H01L 27/3276; H01L 2251/5338; H01L 51/0097

(57) ABSTRACT

A display device includes a resin layer, a film substrate bonded to one surface of the resin layer by using an adhesive layer, a display region provided on another surface of the resin layer opposite to the one surface of the resin layer, and a frame region provided around the display region. In the film substrate, a first slit formed by removing thickness of a film substrate is formed. In the film substrate, the first slit is formed in at least a part of a region overlapping a region between a plurality of input terminals of a driving chip and a plurality of output terminals of the driving chip.

### TECHNICAL FIELD

The present invention relates to a display device.

### BACKGROUND ART

PTL 1 discloses a configuration of suppressing occurrence of disconnection or the like in wiring lines of a flexible wiring line substrate that is provided at an end portion of a display panel, even when the flexible wiring line substrate is bent.

PTL 2 discloses a configuration of suppressing occurrence of disconnection or the like in a solder fillet formed by soldering an electrode portion of an electronic component to a solder land, even when a flexible wiring line substrate obtained by soldering and mounting the electronic component, is bent.

PTL 3 discloses a touch panel having a configuration in which a portion of a flexible wiring line substrate is interposed in a portion between two transparent substrates. In the touch panel, the thickness of the flexible wiring line substrate is fixed, so as to reduce protrusions and recesses on a surface of the flexible wiring line substrate and suppress recesses of each of the two transparent substrates at positions to interpose the flexible wiring line substrate.

### CITATION LIST

### Patent Literature

PTL 1: JP 2016-197178 A (published on Nov. 24, 2016)
PTL 2: JP 2006-140416 A (published on Jun. 1, 2006)
PTL 3: JP 2010-2989 A (published on Jan. 27, 2010)

### SUMMARY OF INVENTION

### Technical Problem

According to the configurations disclosed in PTLs 1 to 3, occurrence of disconnection or the like on the flexible wiring line substrate can be suppressed, and recesses of each of two transparent substrates to interpose the flexible wiring line substrate can be suppressed.

The configurations disclosed in PTLs 1 to 3, however, are inadequate to improve a problem presented in a configuration in which a driving chip including a resin layer, a film substrate bonded to one surface of the resin layer by using an adhesive layer, and a driving chip (IC chip) mounted on another surface of the resin layer by using an anisotropic conductive material is connected on a flexible substrate in the form of a Chip On Plastic (COP).

With reference to FIG. 7, such a problem presented in a configuration in which a driving chip 31 is connected in the form of a COP will be described below.

(a) of FIG. 7 is a diagram illustrating a schematic configuration of a conventional display device 100 on which the driving chip 31 is connected in the form of a COP. (b) of FIG. 7 is a partial enlarged view of the part A of (a) of FIG. 7, which illustrates a state before the driving chip 31 is compression-bonded. (c) of FIG. 7 is a partial enlarged view of the part A of (a) of FIG. 7, which illustrates a state after the driving chip 31 is compression-bonded.

As illustrated in (a) of FIG. 7, the display device 100 includes a resin layer 12, a film substrate 10 bonded to one surface of the resin layer 12 by using an adhesive layer 11, a display region provided on another surface of the resin layer 12 opposite to the one surface of the resin layer 12, and a frame region provided around the display region.

In the display region and the frame region of the display device 100, an inorganic layered film 7 including a barrier layer (inorganic moisture-proof layer), a gate insulating film layer, and a plurality of inorganic insulating film layers is formed.

A source-drain wiring line SH including a source-drain electrode, an organic EL element layer 5, and a sealing layer 6 are formed on the inorganic layered film 7 in the display region, and a plurality of external signal input wiring lines TMm including a terminal portion and a plurality of lead wiring lines TWn electrically connected to the source-drain wiring line SH in the display region are formed on the inorganic layered film 7 in the frame region.

The driving chip 31 is mounted on the plurality of lead wiring lines TWn and the plurality of external signal input wiring lines TMm in the frame region, and a flexible wiring line substrate 33 is provided on the terminal portion of the plurality of external signal input wiring lines TMm.

As illustrated in (b) of FIG. 7, each of a plurality of input terminals 31IBm of the driving chip 31 is disposed on a corresponding one of the plurality of external signal input wiring lines TMm and is electrically connected to the corresponding one of the plurality of external signal input wiring lines TMm by using an anisotropic conductive material 32, and each of a plurality of output terminals 31OBn, 31OBn−1 . . . of the driving chip 31 is disposed on a corresponding one of the plurality of lead wiring lines TWn, TWn−1 . . . and is electrically connected to the corresponding one of the plurality of lead wiring lines TWn, TWn−1 . . . by using the anisotropic conductive material 32.

The state of the driving chip 31 illustrated in (b) of FIG. 7 is a state before the driving chip 31 is compression-bonded. Thus, the adhesive layer 11, the resin layer 12, and the inorganic layered film 7 formed on the film substrate 10 located at a position to overlap a region between the plurality of input terminals 31IBm of the driving chip 31 and the plurality of output terminals 31OBn, 31OBn−1 . . . of the driving chip 31, which corresponds to the part B indicated by the dotted line, are in a flat state.

(c) of FIG. 7 illustrates a state after the driving chip 31 is compression-bonded. When the driving chip 31 is compression-bonded, only the layers located below the plurality of input terminals 31IBm and the plurality of output terminals 31OBn, 31OBn−1 . . . are subjected to the pressure. Thus, in the adhesive layer 11, the adhesive agent flows from portions where the plurality of input terminals 31IBm and the plurality of output terminals 31OBn, 31OBn−1 . . . are present to portions where the plurality of input terminals 31IBm and the plurality of output terminals 31OBn, 31OBn−1 . . . are absent (the adhesive agent flows in the directions indicated by the arrows in (c) of FIG. 7).

For the reason described above, in (c) of FIG. 7, the adhesive layer 11, the resin layer 12, and the inorganic layered film 7 formed on the film substrate 10 located at the position to overlap the region between the plurality of input terminals 31IBm of the driving chip 31 and the plurality of output terminals 31OBn, 31OBn−1 . . . of the driving chip 31, which corresponds to the part B indicated by the dotted line, are in a swelling state.

If a wiring line, a transistor element, or the like is formed in the part B in such a swelling state indicated by the dotted line, the swell may cause disconnection in the wiring line and defects in the transistor element. For this reason, a wiring line, a transistor element, or the like cannot be formed in the part B indicated by the dotted line in the conventional display device 100, which has been presenting a problem of hindering efficient use of the frame region and hindering narrowing of the frame region.

The present invention is made in view of the problem described above, and has an object to provide a display device that is capable of efficient use of a frame region and narrowing of the frame region.

### Solution to Problem

To solve the problem described above, a display device according to the present invention is a display device including: a resin layer; a film substrate bonded to one surface of the resin layer by using an adhesive layer; a display region provided on another surface of the resin layer opposite to the one surface of the resin layer; and a frame region provided around the display region, wherein, in the frame region, a plurality of external signal input wiring lines, a driving chip including a plurality of input terminals and a plurality of output terminals, and a plurality of lead wiring lines extending from the display region are provided, each of the plurality of input terminals of the driving chip is disposed on a corresponding one of the plurality of external signal input wiring lines and is electrically connected to the corresponding one of the plurality of external signal input wiring lines by using an anisotropic conductive material, each of the plurality of output terminals of the driving chip is disposed on a corresponding one of the plurality of lead wiring lines and is electrically connected to the corresponding one of the plurality of lead wiring lines by using the anisotropic conductive material, in the film substrate, a first slit being formed by removing thickness of the film substrate is formed, and in the film substrate, the first slit is formed in at least a part of a region overlapping a region between the plurality of input terminals of the driving chip and the plurality of output terminals of the driving chip.

According to the configuration, in the film substrate, the first slit formed by removing the thickness of the film substrate is formed in at least a part of the region overlapping the region between the plurality of input terminals of the driving chip and the plurality of output terminals of the driving chip.

Thus, when the driving chip is compression-bonded, swelling occurring due to a flow of an adhesive agent can be suppressed. This allows for efficient use of the frame region and narrowing of the frame region.

### Advantageous Effects of Invention

According to one aspect of the present invention, the display device capable of efficient use of the frame region and narrowing of the frame region can be provided.

### BRIEF DESCRIPTION OF DRAWINGS

FIG. 1(a) is a plan view of a flexible organic EL display device according to the first embodiment. FIG. 1(b) is a cross-sectional view of a display region of the flexible organic EL display device according to the first embodiment.

FIG. 2(a) is a diagram illustrating a schematic configuration of the flexible organic EL display device according to the first embodiment. FIG. 2(b) is a partial enlarged view of a part in which a driving chip is compression-bonded. FIG. 2(c) is a diagram illustrating a film substrate provided in the flexible organic EL display device according to the first embodiment.

FIG. 3(a) is a diagram illustrating a plurality of input terminals and a plurality of output terminals in the driving chip provided in the flexible organic EL display device according to the first embodiment. FIG. 3(b) is a diagram illustrating a schematic configuration of a part of the flexible organic EL display device in which the driving chip is compression-bonded according to the first embodiment.

FIG. 4(a) is a diagram illustrating a schematic configuration of a flexible organic EL display device according to the second embodiment. FIG. 4(b) is a partial enlarged view of a part in which a driving chip is compression-bonded. FIG. 4(c) is a diagram illustrating a film substrate provided in the flexible organic EL display device according to the second embodiment.

FIG. 5(a) is a diagram illustrating a schematic configuration of a flexible organic EL display device according to the third embodiment. FIG. 5(b) is a partial enlarged view of a part in which a driving chip is compression-bonded. FIG. 5(c) is a diagram illustrating a film substrate provided in the flexible organic EL display device according to the third embodiment.

FIG. 6(a) is a diagram illustrating a schematic configuration of a flexible organic EL display device according to the fourth embodiment. FIG. 6(b) is a partial enlarged view of a part in which a driving chip is compression-bonded. FIG. 6(c) is a diagram illustrating a film substrate provided in the flexible organic EL display device according to the fourth embodiment.

FIG. 7(a) is a diagram illustrating a schematic configuration of a conventional display device on which a driving chip is connected in the form of a COP. FIG. 7(b) is a partial enlarged view of the part A illustrated in FIG. 7(a), which illustrates a state before the driving chip is compression-bonded. FIG. 7(c) is a partial enlarged view of the part A illustrated in (a), which illustrates a state after the driving chip is compression-bonded.

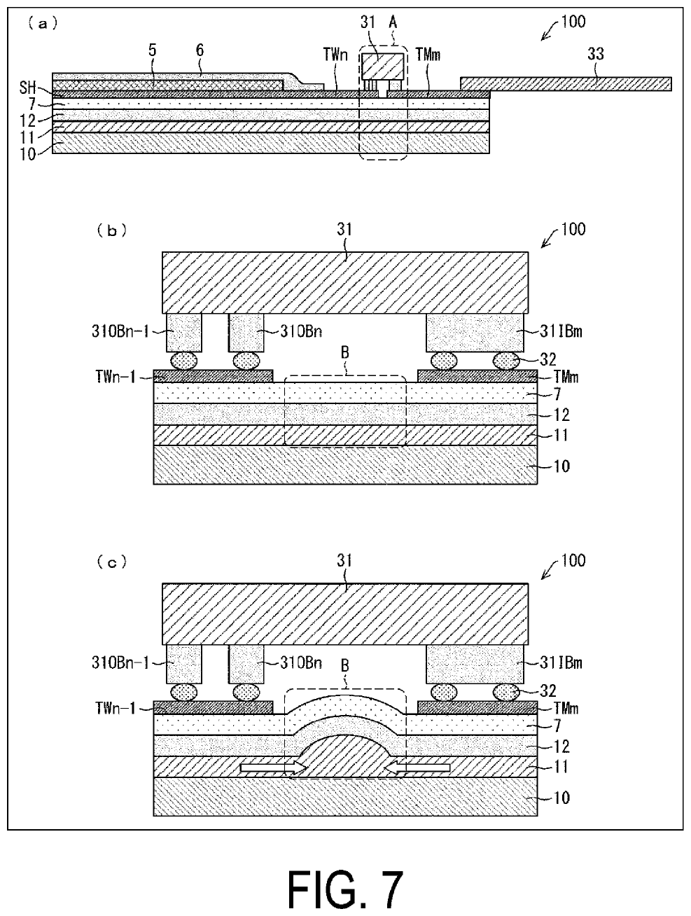

### DESCRIPTION OF EMBODIMENTS

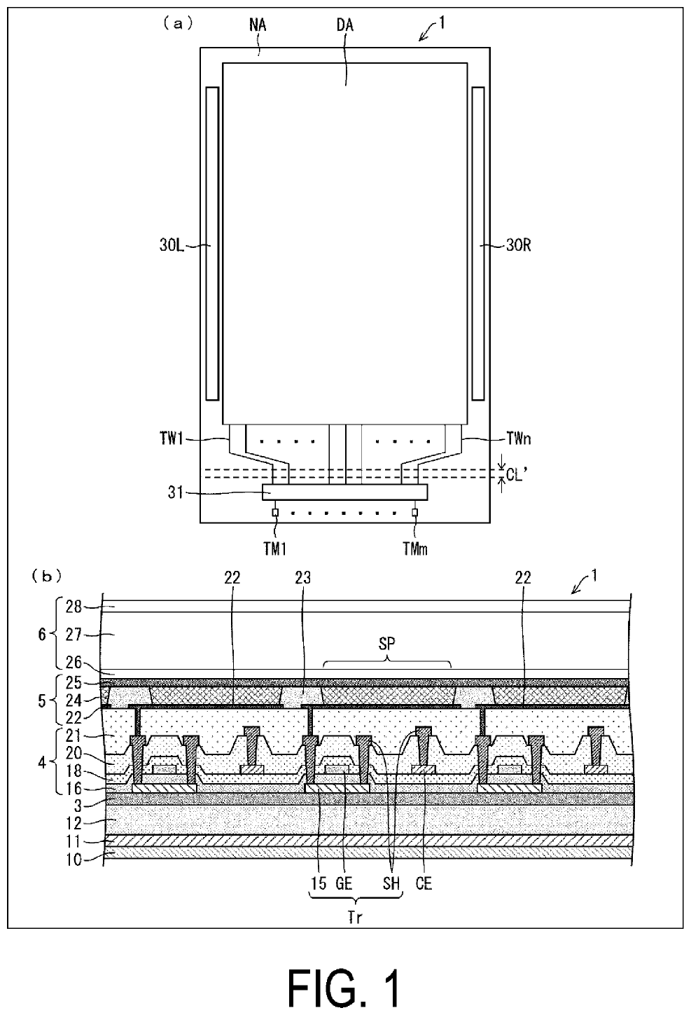

A description follows regarding embodiments of the present invention, with reference to FIGS. 1 to 6. Hereinafter, for convenience of description, components having the same functions as those described in a specific embodiment are denoted by the same reference numerals, and descriptions thereof may be omitted.

Note that, in the following embodiments, description is made of an organic electro luminescence (EL) element as an example of a display element (optical element). However, the embodiment is not limited thereto, and may be, for example, a reflective-type liquid crystal display element, in which luminance and transmittance are controlled by a voltage and backlight is not required.

The display element (optical element) may be an optical element whose luminance and transmittance are controlled by an electric current, and examples of the electric current-controlled optical element include an organic electro luminescence (EL) display provided with an organic light emitting diode (OLED), an EL display such as an inorganic EL display provided with an inorganic light emitting diode, or a quantum dot light emitting diode (QLED) display provided with a QLED.

As a matter of course, the present invention can also be applied to a flexible display device including a display element other than the display element described above.

### First Embodiment

With reference to FIG. 1 to FIG. 3, a flexible organic EL display device 1 according to the first embodiment of the present invention will be described below.

(a) of FIG. 1 is a plan view of the flexible organic EL display device 1 according to the first embodiment. (b) of FIG. 1 is a cross-sectional view of a display region DA of the flexible organic EL display device 1 according to the first embodiment.

With reference to (a) of FIG. 1 and (b) of FIG. 1, a process of manufacturing the flexible organic EL display device 1 will be described.

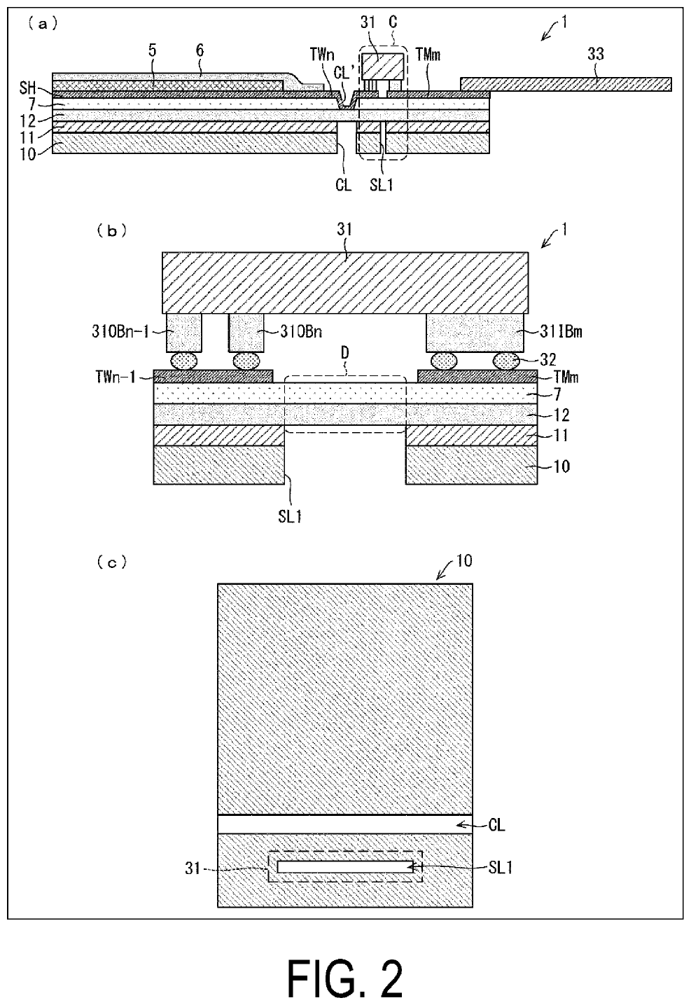

First, a resin layer 12 is formed above a transparent support substrate (for example, a mother glass substrate) that is removed and replaced with a film substrate 10 in a later process (step S1). Next, a barrier layer 3 is formed (step S2). Next, a TFT layer 4 including a plurality of external signal input wiring lines TM1 to TMm including a terminal portion and a plurality of lead wiring lines TW1 to TWn electrically connected to a source-drain wiring line SH in the display region DA is formed (step S3). Next, an organic EL element layer 5, i.e., a light-emitting element layer, is formed as a display element (step S4). Next, a sealing layer 6 is formed (step S5). Next, an upper face film (not illustrated) is bonded onto the scaling layer 6 (step S6). Note that it goes without saying that the step of bonding the upper face film (not illustrated) onto the sealing layer 6 can be omitted as appropriate when, for example, a touch panel is provided on the sealing layer 6 by using an adhesive layer. Next, a lower face of the resin layer 12 is irradiated with laser light through the support substrate to reduce a bonding force between the support substrate and the resin layer 12, and the support substrate is peeled from the resin layer 12 (step S7). This step is also referred to as a Laser Lift Off process (LLO process). Next, the film substrate 10 is bonded to the face of the resin layer 12 from which the support substrate was peeled off with an adhesive layer 11 therebetween (step S8). Next, a layered body including the film substrate 10, the adhesive layer 11, the resin layer 12, the barrier layer 3, the TFT layer 4, the organic EL element layer 5, the sealing layer 6, and the upper face film is partitioned and a plurality of individual pieces are obtained (step S9). Next, a flexible wiring line substrate 33 (illustrated in (a) of FIG. 2) is bonded and mounted onto the terminal portion included in the plurality of external signal input wiring lines TM1 to TMm with pressure by using an anisotropic conductive material (also referred to as an anisotropic conductive film (ACF)), and a driving chip 31 is bonded and mounted on the plurality of external signal input wiring lines TM1 to TMm and the plurality of lead wiring lines TW1 to TWn with pressure by using the anisotropic conductive material. (step S10). Next, edge folding processing (processing of performing 180-degree bending at a bending slit (third slit) CL′ illustrated in (a) of FIG. 1) is performed to make a flexible organic EL display device 1 (step S11). Next, an inspection for wire breaking is performed, and in a case where there is breaking of any wire, correction is performed (step S12).

As illustrated in (a) of FIG. 1, the present embodiment provides description by taking an example of a case in which two gate drivers 30R, 30L are formed in a gate driver monolithic (GDM) configuration in a frame region NA on the right and left sides of the display region DA of the flexible organic EL display device 1. However, this is not restrictive, and the gate drivers formed in a gate driver monolithic (GDM) configuration may be provided in the display region DA. The gate drivers may not be formed in a gate driver monolithic (GDM) configuration, and the gate drivers may be externally attached, for example.

Note that “to form the gate drivers in a gate driver monolithic (GDM) configuration” means that a plurality of transistors included in each of the gate drivers are formed using the same material as a plurality of transistors included in the TFT layer 4 provided in the display region DA.

Examples of the material of the film substrate 10 include polyethylene terephthalate (PET), but are not limited thereto.

Examples of the adhesive layer 11 include an optical clear adhesive (OCA) and an optical clear resin (OCR), but are not limited thereto.

Examples of the material of the resin layer 12 include a polyimide resin, an epoxy resin, and a polyamide resin, but are not limited thereto.

The barrier layer 3 is a layer that inhibits moisture or impurities from reaching the TFT layer 4 and the organic EL element layer 5 when the flexible organic EL display device 1 is in use, and may consist of, for example, a silicon oxide film, a silicon nitride film, or a silicon oxynitride film, or of a layered film of these films, each of which is formed by means of chemical vapor deposition (CVD).

The TFT layer 4 is provided on a layer above the resin layer 12 and the barrier layer 3. The TFT layer 4 includes a semiconductor film 15, an inorganic insulating film (a gate insulating film layer) 16 as an upper layer of the semiconductor film 15, a gate electrode GE as an upper layer of the inorganic insulating film 16, an inorganic insulating film 18 as an upper layer of the gate electrode GE, a capacitance wiring line CE as an upper layer of the inorganic insulating film 18, an inorganic insulating film 20 as an upper layer of the capacitance wiring line CE, a source-drain wiring line SH including a source-drain electrode as an upper layer of the inorganic insulating film 20, and a flattening film 21 as an upper layer of the source-drain wiring line SH.

A thin film transistor Tr (TFT) as an active element is configured so as to include the semiconductor film 15, the inorganic insulating film 16, the gate electrode GE, the inorganic insulating film 18, the inorganic insulating film 20, and the source-drain wiring line SH.

The semiconductor film 15 is formed of low-temperature polysilicon (LTPS) or an oxide semiconductor, for example. Note that, although the TFT provided with the semiconductor film 15 as the channel is illustrated as having a top gate structure in (b) of FIG. 1, the TFT may have a bottom gate structure (when the TFT channel is an oxide semiconductor, for example).

Each of the gate electrodes GE, the capacitance electrodes CE, the source-drain wiring line SH, the plurality of external signal input wiring lines TM1 to TMm, and the plurality of lead wiring lines TW1 to TWn is formed of, for example, a monolayer film or a layered film of metal containing at least one of aluminum (Al), tungsten (W), molybdenum (Mo), tantalum (Ta), chromium (Cr), titanium (Ti), and copper (Cu).

The inorganic insulating films 16, 18, 20 may be, for example, formed of a silicon oxide (SiOx) film, a silicon nitride (SiNx) film, or a silicon oxynitride film, or of a layered film of these, each of which is formed by means of the CVD method.

The flattening film (interlayer insulating film) 21 may be formed, for example, of a coatable photosensitive organic material, such as a polyimide resin and an acrylic resin.

Note that, in the flexible organic EL display device 1, a common multi-layer inorganic film is formed in the display region DA and the frame region NA. The common multi-layer inorganic film includes the barrier layer 3, the inorganic insulating film 16, the inorganic insulating film 18, and the inorganic insulating film 20.

In the frame region NA disposed on the outside of the display region DA of the flexible organic EL display device illustrated in (a) of FIG. 1, the gate drivers 30R, 30L, the driving chip 31, the plurality of external signal input wiring lines TM1 to TMm including a terminal portion, the plurality of lead wiring lines TW1 to TWn electrically connected the source-drain wiring line SH in the display region DA, and the bending slit CL′ are provided.

The organic EL element layer 5 includes an anode 22 as an upper layer of the flattening film 21, a bank 23 that covers an edge of the anode 22, an electroluminescence (EL) layer 24 as an upper layer of the anode 22, and a cathode 25 as an upper layer of the EL layer 24. For each of subpixels SP, the organic EL element layer 5 includes the anode 22 having an island shape, the EL layer 24, and the cathode 25. The bank 23 (anode edge cover) 23 can be formed of a coatable photosensitive organic material, such as a polyimide resin or an acrylic resin, for example. The organic EL element layer 5 forms the display region DA and is provided on a layer above the TFT layer 4.

For example, the EL layer 24 is formed by layering a hole injection layer, a hole transport layer, a light-emitting layer, an electron transport layer, and an electron injection layer in this order, from the lower layer side. The light-emitting layer is formed in an island shape for each subpixel by a vapor deposition method or ink-jet method, and the other layers, by contrast, may be a solid-like common layer. A configuration is also possible in which one or more layers are not formed, out of the hole injection layer, the hole transport layer, the electron transport layer, and the electron injection layer.

The anode (anode electrode) 22 is light reflectivity and is formed by layering Indium Tin Oxide (ITO) and an alloy containing Ag, for example. The cathode 25 may be formed of a transparent conductive material such as Indium Tin Oxide (ITO) or Indium Zinc Oxide (IZO).

Holes and electrons are recombined in the EL layer 24 by a drive current between the anode 22 and the cathode 25 in the organic EL element layer 5, and the excitons generated thereby fall to the ground state such that light is emitted. Since the cathode 25 is transparent and the anode 22 has light reflectivity, the light emitted from the EL layer 24 travels upward and becomes top-emitting.

The sealing layer 6 is transparent, and includes a first inorganic sealing film 26 that covers the cathode 25, an organic sealing film 27 that is formed on the first inorganic sealing film 26, and a second inorganic sealing film 28 that covers the organic sealing film 27. The sealing layer 6 covering the organic EL element layer 5 inhibits foreign matters, such as water and oxygen, from penetrating to the organic EL element layer 5.

Each of the first inorganic sealing film 26 and the second inorganic sealing film 28 may be formed of, for example, a silicon oxide film, a silicon nitride film, or a silicon oxynitride film, or of a layered film of these, each of which is formed by means of CVD. The organic sealing film 27 is a transparent organic film that is thicker than each of the first inorganic sealing film 26 and the second inorganic sealing film 28, and can be formed of a coatable photosensitive organic material such as a polyimide resin or an acrylic resin.

(a) of FIG. 2 is a diagram illustrating a schematic configuration of the flexible organic EL display device 1 on which the driving chip 31 is connected in the form of a COP. (b) of FIG. 2 is a partial enlarged view of the part C of (a) of FIG. 2, which illustrates a state after the driving chip 31 is compression-bonded. (c) of FIG. 2 is a diagram illustrating the film substrate 10 provided in the flexible organic EL display device 1.

As illustrated in (a) of FIG. 2, the flexible organic EL display device 1 includes the resin layer 12, the film substrate 10 bonded to one surface (lower face) of the resin layer 12 by using the adhesive layer 11, the display region DA provided on another surface (upper face) of the resin layer 12 opposite to the one surface of the resin layer 12, and the frame region NA provided around the display region DA.

In the display region DA and the frame region NA of the flexible organic EL display device 1, an inorganic layered film 7 including the barrier layer 3, the inorganic insulating film 16, the inorganic insulating film 18, and the inorganic insulating film 20 is formed.

The present embodiment provides description by taking an example of a case in which the inorganic layered film 7 is formed in the entire frame region NA. However, the inorganic layered film 7 may be formed only in a part of the frame region NA, or need not be formed in the frame region NA. Only some of the films constituting the inorganic layered film 7 may be formed in the frame region NA.

The source-drain wiring line SH including a source-drain electrode, the organic EL element layer 5, and the scaling layer 6 are formed on the inorganic layered film 7 in the display region DA, and a plurality of external signal input wiring lines TMm including a terminal portion and a plurality of lead wiring lines TWn electrically connected to the source-drain wiring line SH in the display region DA are formed on the inorganic layered film 7 in the frame region NA.

The driving chip 31 is mounted on the plurality of lead wiring lines TWn and the plurality of external signal input wiring lines TMm in the frame region NA, and the flexible wiring line substrate 33 is provided on the terminal portion of the plurality of external signal input wiring lines TMm.

In the film substrate 10 and the adhesive layer 11, a first slit SL1 and a second slit CL, each of which is formed by removing the thickness of the film substrate 10 and the thickness of the adhesive layer 11, are formed so as to expose the resin layer 12.

In the present embodiment, the first slit SL1 and the second slit CL are formed by using a laser. However, this is not restrictive.

The present embodiment provides description by taking an example of a case in which the first slit SL1 is formed by removing the thickness of the film substrate 10 and the thickness of the adhesive layer 11. However, this is not restrictive. It is only necessary that the first slit SL1 be formed by removing at least the thickness of the film substrate 10.

The present embodiment provides description by taking an example of a case in which the second slit CL is formed by removing the thickness of the film substrate 10 and the thickness of the adhesive layer 11. However, this is not restrictive. It is only necessary that the second slit CL be formed by removing at least a part of the thickness of the film substrate 10.

As illustrated in (a) of FIG. 2 and (c) of FIG. 2, the second slit CL is formed from one end portion of each of the film substrate 10 and the adhesive layer 11 to another end portion thereof in a direction orthogonal to a direction in which the plurality of lead wiring lines TWn extend toward the display region DA, so that the second slit CL intersects the plurality of lead wiring lines TWn in plan view.

As illustrated in (a) of FIG. 2, a bending slit (third slit) CL′ is formed in the inorganic layered film 7 that is formed between the resin layer 12 and the plurality of lead wiring lines TWn in the frame region NA.

The present embodiment provides description by taking an example of a case in which the bending slit (third slit) CL′ is formed by removing the thickness of the inorganic layered film 7 so as to expose the resin layer 12. However, this is not restrictive. It is only necessary that the bending slit (third slit) CL′ be formed by removing at least a part of the thickness of the inorganic layered film 7.

It is only necessary that the bending slit (third slit) CL′ be formed to intersect the plurality of lead wiring lines TWn in at least a part of the inorganic layered film 7 overlapping the second slit CL. In the present embodiment, the bending slit (third slit) CL′ is formed in the entire region of the inorganic layered film 7 overlapping the second slit CL.

Note that, in the present embodiment, both the second slit CL and the bending slit (third slit) CL′ are formed in order to further facilitate bending of the flexible organic EL display device 1. However, this is not restrictive, and only either the second slit CL or the bending slit (third slit) CL′ may be formed.

As illustrated in (b) of FIG. 2, after the driving chip 31 is compression-bonded, each of a plurality of input terminals 31IBm of the driving chip 31 is disposed on a corresponding one of the plurality of external signal input wiring lines TMm and is electrically connected to the corresponding one of the plurality of external signal input wiring lines TMm by using an anisotropic conductive material 32, and each of a plurality of output terminals 31OBn, 31OBn−1 . . . of the driving chip 31 is disposed on a corresponding one of the plurality of lead wiring lines TWn, TWn−1 . . . and is electrically connected to the corresponding one of the plurality of lead wiring lines TWn, TWn−1 . . . by using the anisotropic conductive material 32.

When the driving chip 31 is compression-bonded, only the layers located below the plurality of input terminals 31IBm and the plurality of output terminals 31OBn, 31OBn−1 . . . are subjected to the pressure. Thus, in the adhesive layer 11, the adhesive agent flows from portions where the plurality of input terminals 31IBm and the plurality of output terminals 31OBn, 31OBn−1 . . . are present to portions where the plurality of input terminals 31IBm and the plurality of output terminals 31OBn, 31OBn−1 . . . are absent.

Although not illustrated, due to the flow of the adhesive agent in the adhesive layer 11, the adhesive agent may in some cases enter the first slit SL1.

In the flexible organic EL display device 1, in the film substrate 10 and the adhesive layer 11, the first slit SL1 is formed in at least a part of a region overlapping a region between the plurality of input terminals 31IBm of the driving chip 31 and the plurality of output terminals 31OBn, 31OBn−1 . . . of the driving chip 31. Thus, even if the adhesive agent flows, the resin layer 12 and the inorganic layered film 7 located at a position to overlap the region between the plurality of input terminals 31IBm of the driving chip 31 and the plurality of output terminals 31OBn, 31OBn−1 . . . of the driving chip 31, which corresponds to the part D indicated by the dotted line illustrated in (b) of FIG. 2, remain in a flat state even after the driving chip 31 is compression-bonded.

As illustrated in (c) of FIG. 2, the first slit SL1 and the second slit CL are formed in the film substrate 10 provided in the flexible organic EL display device 1.

In the film substrate 10, the second slit CL is formed in a part from one end portion to another end portion in the direction orthogonal to the direction in which the plurality of lead wiring lines TWn, TWn−1 . . . extend toward the display region DA.

In the present embodiment, in consideration of deterioration of rigidity of the film substrate 10, in the film substrate 10, the first slit SL1 is formed only in a part between the inside of one end portion and the inside of another end portion in the direction orthogonal to the direction in which the plurality of lead wiring lines TWn, TWn−1 . . . extend toward the display region DA and in a region of the film substrate 10 overlapping the driving chip 31 as indicated by the dotted line in (c) of FIG. 2. However, this is not restrictive. In the film substrate 10, the first slit SL1 may be formed from one end portion to another end portion in the direction orthogonal to the direction in which the plurality of lead wiring lines TWn, TWn−1 . . . extend toward the display region DA, as with the second slit CL.

In the present embodiment, the first slit SL1 is formed as one slit having an island shape. However, this is not restrictive. As in the third and fourth embodiments to be described later, the first slit SL1 may be formed as a plurality of slits each having an island shape.

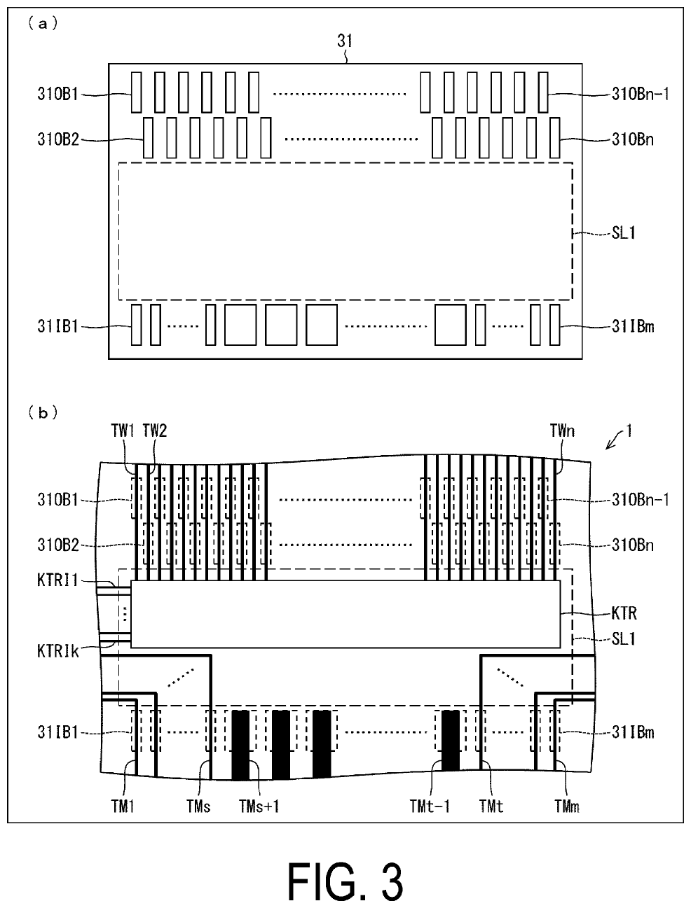

(a) of FIG. 3 is a diagram illustrating the plurality of input terminals 31IBm and the plurality of output terminals 31OBn in the driving chip 31 provided in the flexible organic EL display device 1. (b) of FIG. 3 is a diagram illustrating a schematic configuration of a part of the flexible organic EL display device 1 in which the driving chip 31 is compression-bonded.

As illustrated in (a) of FIG. 3, the plurality of output terminals 31OB1 to 31OBn in the driving chip 31 are formed in two rows. The first row includes the output terminals 31OB1, 31OB3 . . . 31OBn−1, and the second row includes the output terminals 31OB2, 31OB4 . . . 31OBn.

Such formation of the output terminals in two rows as described above allows for securing of a larger distance between adjacent output terminals in the same row.

The present embodiment provides description by taking an example of a case in which the output terminals are formed in two rows. However, this is not restrictive. The output terminals of the driving chip 31 may be formed in one row, or may be formed in three or more rows.

In the present embodiment, as illustrated in (a) of FIG. 3, the plurality of input terminals 31IB1 to 31IBm in the driving chip 31 are formed in one row. However, this is not restrictive. The input terminals may also be formed in a plurality of rows as in the case of the output terminals.

Note that a region between the plurality of input terminals 31IB1 to 31IBm of the driving chip 31 and the plurality of output terminals 31OB1 to 31OBn of the driving chip 31 refers to a region defined by a line extended from a straight line that connects an upper end portion of one of the plurality of input terminals 31IB1 to 31IBm in (a) of FIG. 3 and upper end portions of input terminals adjacent to the one of the plurality of input terminals 31IB1 to 31IBm, a line extended from a straight line that connects a lower end portion of one of the plurality of output terminals 31OB1 to 31OBn in (a) of FIG. 3 and lower end portions of output terminals adjacent to the one of the plurality of output terminals 31OB1 to 31OBn in the first row and the second row, and two straight lines that connect both ends of the two lines mentioned above.

In (a) of FIG. 3, the first slit SL1 is indicated by the dotted line for the sake of illustration of the size of the first slit SL1 in comparison to the driving chip 31.

The present embodiment illustratively provides a case in which the first slit SL1 is formed in the adhesive layer 11 and the film substrate 10 in a part of a region overlapping the region between the plurality of input terminals 31IB1 to 31IBm of the driving chip 31 and the plurality of output terminals 31OB1 to 31OBn of the driving chip 31. In this case, the width of the first slit SL1 in the vertical direction is smaller than the width of the region between the plurality of input terminals 31IB1 to 31IBm of the driving chip 31 and the plurality of output terminals 31OB1 to 31OBn of the driving chip 31 in the vertical direction, and the width of the first slit SL1 in the horizontal direction is larger than the width of the region between the plurality of input terminals 31IB1 to 31IBm of the driving chip 31 and the plurality of output terminals 31OB1 to 31OBn of the driving chip 31 in the horizontal direction.

The first slit SL1, however, is not limited to that described above. It is only necessary that the first slit SL1 be formed in the adhesive layer 11 and the film substrate 10 in at least a part of a region overlapping the region between the plurality of input terminals 31IB1 to 31IBm of the driving chip 31 and the plurality of output terminals 31OB1 to 31OBn of the driving chip 31.

As illustrated in (b) of FIG. 3, after the driving chip 31 is compression-bonded, each of the plurality of input terminals 31IB1 to 31IBm of the driving chip 31 indicated by the dotted line is disposed on a corresponding one of the plurality of external signal input wiring lines TM1 to TMm, and each of the plurality of output terminals 31OB1 to, 31OBn of the driving chip 31 indicated by the dotted line is disposed on a corresponding one of the plurality of lead wiring lines TW1 to TWn.

In the frame region NA of the flexible organic EL display device 1, an inspection transistor group KTR including a plurality of inspection transistors is formed so as to overlap the first slit SL1 indicated by the dotted line.

Each of the plurality of inspection transistors (not illustrated) of the inspection transistor group KTR is shifted to either an ON state or an OFF state, depending on whether a signal input to a gate electrode of each of the plurality of inspection transistors is High or Low.

When one of the plurality of inspection transistors is in an ON state, an inspection signal is input to a source electrode of the one of the plurality of inspection transistors via a corresponding one of a plurality of inspection wiring lines KTRI1 to KTRIk. The inspection signal is output from at least a part of the plurality of lead wiring lines TW1 to TWn via a drain electrode of the one of the plurality of inspection transistors.

Note that, in the present embodiment, the plurality of inspection transistors of the inspection transistor group KTR are formed using the same material as the plurality of transistors included in the TFT layer 4 provided in the display region DA and the plurality of transistors included in each of the gate drivers. However, this is not restrictive.

In the flexible organic EL display device 1, the first slit SL1 is formed. Owing to the first slit SL1, the resin layer 12 and the inorganic layered film 7 located at a position to overlap a region between the plurality of input terminals 31IB1 to 31IBm of the driving chip 31 and the plurality of output terminals 31OB1 to 31OBn of the driving chip 31 remain in a flat state even after the driving chip 31 is compression-bonded.

Accordingly, as illustrated in (b) of FIG. 3, in the flexible organic EL display device 1, the inspection transistor group KTR including the plurality of inspection transistors, a part of the plurality of lead wiring lines TW1 to TWn, a part of the plurality of inspection wiring lines KTRI1 to KTRIk, and a part of the plurality of external signal input wiring lines TM1 to TMm can be formed to overlap the first slit SL1. This configuration allows for efficient use of the frame region NA and narrowing of the frame region.

Note that the present embodiment provides description by taking an example of a case in which the plurality of lead wiring lines TW1 to TWn and the plurality of external signal input wiring lines TM1 to TMm are formed using the same material as the source-drain wiring line SH, and the plurality of inspection wiring lines KTRI1 to KTRIk are formed using the same material as the gate electrode GE being a layer lower than that of the source-drain wiring line SH. However, this is not restrictive.

Note that, of the plurality of external signal input wiring lines TM1 to TMm, the wiring lines TM1 to TMs disposed at a right end portion are wiring lines for inputting an external signal to the gate driver 30R that is formed in the gate driver monolithic (GDM) configuration illustrated in (a) of FIG. 1. Of the plurality of external signal input wiring lines TM1 to TMm, the wiring lines TMt to TMm disposed at a left end portion, by contrast, are wiring lines for inputting an external signal to the gate driver 30L that is formed in the gate driver monolithic (GDM) configuration illustrated in (a) of FIG. 1.

As illustrated in (b) of FIG. 3, in the flexible organic EL display device 1, a part of the wiring lines TM1 to TMs and a part of the wiring lines TMt to TMm are formed to overlap the first slit SL1.

Note that, in the present embodiment, the driving chip 31 included in the flexible organic EL display device 1 is a source driver.

As described above, the present embodiment achieves narrowing of the frame region of the flexible organic EL display device 1 by forming both the plurality of wiring lines and the plurality of inspection transistors so as to overlap the first slit SL1.

However, this is not restrictive. The present embodiment may achieve narrowing of the frame region of the flexible organic EL display device 1 by forming only either the plurality of wiring lines or the plurality of inspection transistors so as to overlap the first slit SL.

The present embodiment has provided description by using the inspection transistors as an example of elements to be formed to overlap the first slit SL1. However, this is not restrictive. Other examples of such elements to be formed to overlap the first slit SL1 may include active elements such as transistor elements or passive elements such as resistor elements or capacitance elements.

### Second Embodiment

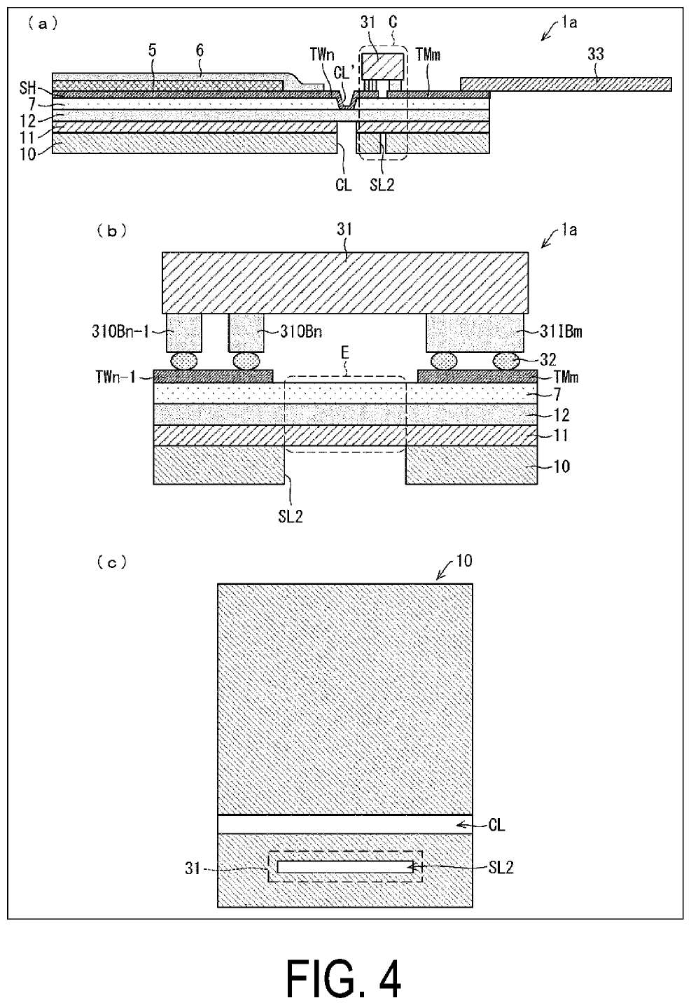

Next, with reference to FIG. 4, the second embodiment of the present invention will be described. A flexible organic EL display device 1a according to the present embodiment is different from the first embodiment in the following respects: In the flexible organic EL display device 1a, a first slit SL2 is one slit having an island shape that is formed by removing the thickness of the film substrate 10. Other configurations are the same as those described in the first embodiment. For convenience of description, members having the same functions as those of the members illustrated in the drawings in the first embodiment are denoted by the same reference numerals, and descriptions thereof will be omitted.

(a) of FIG. 4 is a diagram illustrating a schematic configuration of the flexible organic EL display device 1a. (b) of FIG. 4 is a partial enlarged view of the part C of (a) of FIG. 4 in which the driving chip 31 is compression-bonded. (c) of FIG. 4 is a diagram illustrating the film substrate 10 provided in the flexible organic EL display device 1a.

As illustrated in (a) of FIG. 4 to (c) of FIG. 4, the first slit SL2 is one slit having an island shape that is formed by removing the thickness of the film substrate 10 in the film substrate 10.

In the film substrate 10, a region for forming the first slit SL2 is similar to that for the first slit SL1 according to the first embodiment described above, and thus description thereof will be herein omitted.

In the flexible organic EL display device 1a, the first slit SL2 is formed. Owing to the first slit SL2, the resin layer 12 and the inorganic layered film 7 located at a position to overlap a region between the plurality of input terminals 31IBm of the driving chip 31 and the plurality of output terminals 31OBn, 31OBn−1 . . . of the driving chip 31, which corresponds to the part E indicated by the dotted line illustrated in (b) of FIG. 4, remain in a flat state even after the driving chip 31 is compression-bonded.

Although not illustrated, the adhesive agent in the adhesive layer 11 may in some cases enter the first slit SL2.

In the flexible organic EL display device 1a, the plurality of inspection transistors, various wiring lines, and the like can be formed to overlap the first slit SL2. This configuration allows for efficient use of the frame region NA and narrowing of the frame region.

Note that, in the present embodiment, the first slit SL2 is formed as one slit having an island shape. However, this is not restrictive. In consideration of deterioration of rigidity of the film substrate 10, it is preferable that the first slit SL2 be formed as a plurality of slits each having an island shape, as in the case of the third and fourth embodiments to be described later.

### Third Embodiment

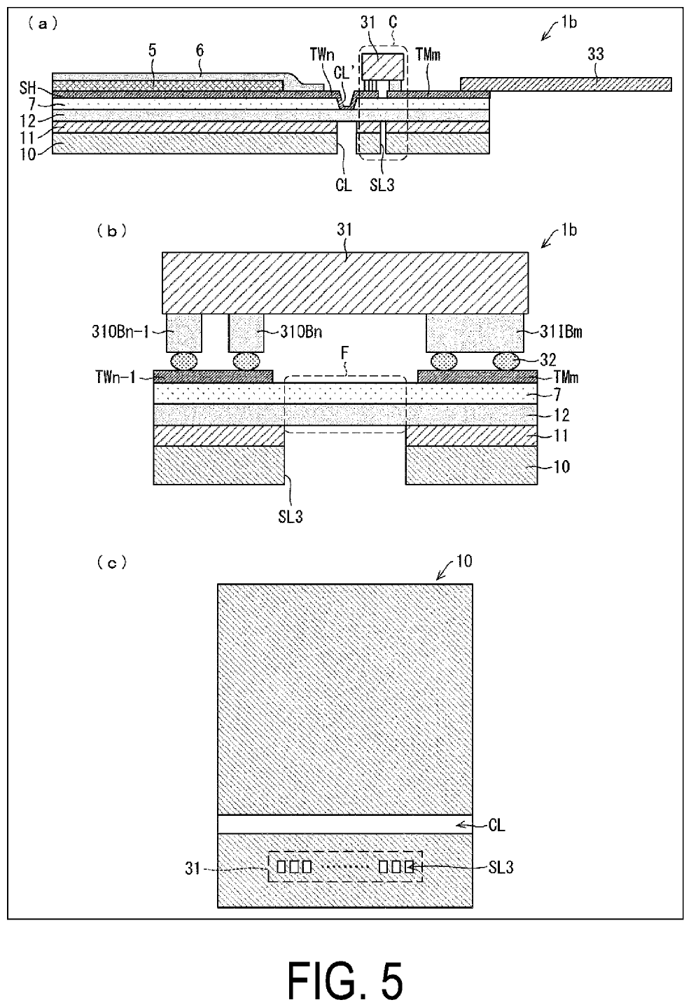

Next, with reference to FIG. 5, the third embodiment of the present invention will be described. A flexible organic EL display device 1b according to the present embodiment is different from the first embodiment in the following respects: In the flexible organic EL display device 1b, a first slit SL3 is formed as a plurality of slits each having an island shape. Other configurations are the same as those described in the first embodiment. For convenience of description, members having the same functions as those of the members illustrated in the drawings in the first embodiment are denoted by the same reference numerals, and descriptions thereof will be omitted.

(a) of FIG. 5 is a diagram illustrating a schematic configuration of the flexible organic EL display device 1b. (b) of FIG. 5 is a partial enlarged view of the part C of (a) of FIG. 5 in which the driving chip 31 is compression-bonded. (c) of FIG. 5 is a diagram illustrating the film substrate 10 provided in the flexible organic EL display device 1b.

As illustrated in (a) of FIG. 5 to (c) of FIG. 5, the first slit SL3 is a plurality of slits each having an island shape that are formed by removing the thickness of the adhesive layer 11 and the thickness of the film substrate 10 in the film substrate 10 and the adhesive layer 11.

In the film substrate 10 and the adhesive layer 11, a region for forming the first slit SL3 is similar to that for the first slit SL according to the first embodiment described above, and thus description thereof will be herein omitted.

In the flexible organic EL display device 1b, the first slit SL3 is formed. Owing to the first slit SL3, the resin layer 12 and the inorganic layered film 7 located at a position to overlap a region between the plurality of input terminals 31IBm of the driving chip 31 and the plurality of output terminals 31OBn, 31OBn−1 . . . of the driving chip 31, which corresponds to the part F indicated by the dotted line illustrated in (b) of FIG. 5, remain in a flat state even after the driving chip 31 is compression-bonded.

Although not illustrated, due to the flow of the adhesive agent in the adhesive layer 11, the adhesive agent may in some cases enter the first slit SL3.

In the flexible organic EL display device 1b, the plurality of inspection transistors, various wiring lines, and the like can be formed to overlap the first slit SL3. This configuration allows for efficient use of the frame region NA and narrowing of the frame region.

The first slit SL3 is a plurality of slits each having an island shape. This configuration allows for suppression of deterioration of rigidity of the film substrate 10.

### Fourth Embodiment

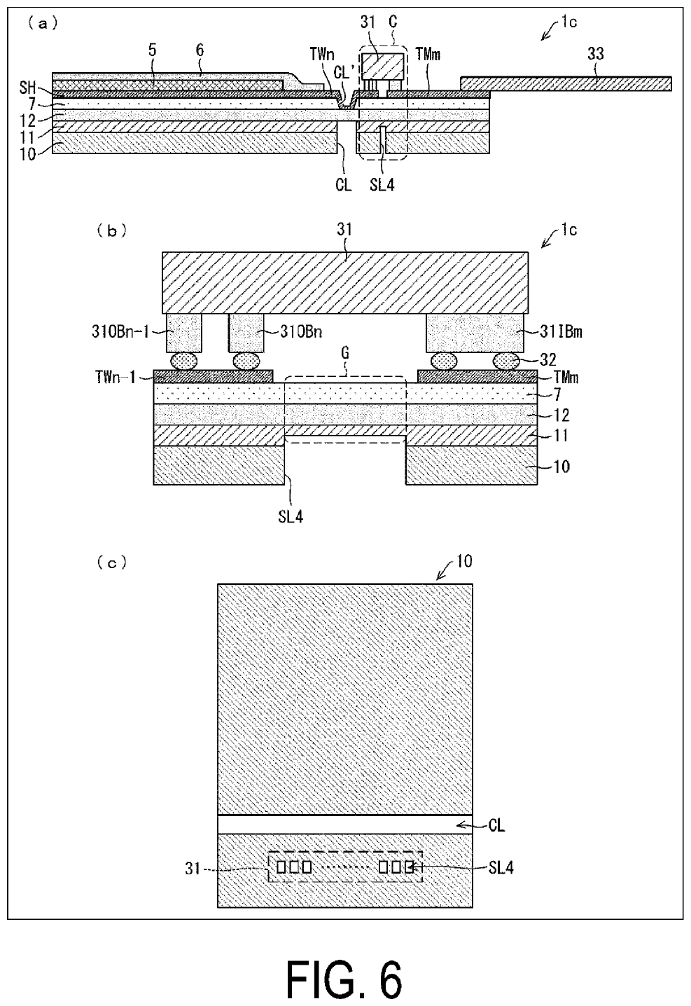

Next, with reference to FIG. 6, the fourth embodiment of the present invention will be described. A flexible organic EL display device 1c according to the present embodiment is different from the first to third embodiments in the following respects: In the flexible organic EL display device 1c, a first slit SL4 is a plurality of slits each having an island shape that are formed by removing a part of the thickness of the adhesive layer 11 and the thickness of the film substrate 10 in the adhesive layer 11 and the film substrate 10. Other configurations are the same as those described in the first to third embodiments. For convenience of description, members having the same functions as those of the members illustrated in the drawings in the first to third embodiments are denoted by the same reference numerals, and descriptions thereof will be omitted.

(a) of FIG. 6 is a diagram illustrating a schematic configuration of the flexible organic EL display device 1c. (b) of FIG. 6 is a partial enlarged view of the part C of (a) of FIG. 6 in which the driving chip 31 is compression-bonded. (c) of FIG. 6 is a diagram illustrating the film substrate 10 provided in the flexible organic EL display device 1c.

As illustrated in (a) of FIG. 6 to (c) of FIG. 6, the first slit SL4 is a plurality of slits each having an island shape that are formed by removing a part of the thickness of the adhesive layer 11 and the thickness of the film substrate 10 in the adhesive layer 11 and the film substrate 10.

In the film substrate 10 and the adhesive layer 11, a region for forming the first slit SL4 is similar to that for the first slit SL1 according to the first embodiment described above, and thus description thereof will be herein omitted.

In the flexible organic EL display device 1c, the first slit SL4 is formed. Owing to the first slit SL4, the resin layer 12 and the inorganic layered film 7 located at a position to overlap a region between the plurality of input terminals 31IBm of the driving chip 31 and the plurality of output terminals 31OBn, 31OBn−1 . . . of the driving chip 31, which corresponds to the part G indicated by the dotted line illustrated in (b) of FIG. 6, remain in a flat state even after the driving chip 31 is compression-bonded.

Although not illustrated, the adhesive agent in the adhesive layer 11 may in some cases enter the first slit SL4.

In the flexible organic EL display device 1c, the plurality of inspection transistors, various wiring lines, and the like can be formed to overlap the first slit SL4. This configuration allows for efficient use of the frame region NA and narrowing of the frame region.

The first slit SL4 is a plurality of slits each having an island shape. This configuration allows for suppression of deterioration of rigidity of the film substrate 10.

Note that the present embodiment has provided description by taking an example of a case in which the first slit SL4 is a plurality of slits each having an island shape that are formed by removing a part of the thickness of the adhesive layer 11 and the thickness of the film substrate 10 in the adhesive layer 11 and the film substrate 10. However, this is not restrictive. The first slit SL4 may be one slit having an island shape that is formed by removing a part of the thickness of the adhesive layer 11 and the thickness of the film substrate 10 in the adhesive layer 11 and the film substrate 10.

### Supplement

### First Aspect

A display device including: a resin layer; a film substrate bonded to one surface of the resin layer by using an adhesive layer; a display region provided on another surface of the resin layer opposite to the one surface of the resin layer; and a frame region provided around the display region, wherein, in the frame region, a plurality of external signal input wiring lines, a driving chip including a plurality of input terminals and a plurality of output terminals, and a plurality of lead wiring lines extending from the display region are provided, each of the plurality of input terminals of the driving chip is disposed on a corresponding one of the plurality of external signal input wiring lines and is electrically connected to the corresponding one of the plurality of external signal input wiring lines by using an anisotropic conductive material, each of the plurality of output terminals of the driving chip is disposed on a corresponding one of the plurality of lead wiring lines and is electrically connected to the corresponding one of the plurality of lead wiring lines by using the anisotropic conductive material, in the film substrate, a first slit being formed by removing thickness of the film substrate is formed, and in the film substrate, the first slit is formed in at least a part of a region overlapping a region between the plurality of input terminals of the driving chip and the plurality of output terminals of the driving chip.

### Second Aspect

The display device according to the first aspect, wherein in the adhesive layer and the film substrate, the first slit is formed by removing at least a part of thickness of the adhesive layer and the thickness of the film substrate, and the first slit is formed in the adhesive layer and the film substrate in at least a part of a region overlapping a region between the plurality of input terminals of the driving chip and the plurality of output terminals of the driving chip.

### Third Aspect

The display device according to the first or second aspect, wherein in the film substrate, the first slit is formed between inside of one end portion and inside of another end portion in a direction orthogonal to a direction in which the plurality of lead wiring lines extend toward the display region.

### Fourth Aspect

The display device according to any one of the first to third aspects, wherein at least in the film substrate of the adhesive layer and the film substrate, a second slit being formed by removing at least a part of the thickness of the film substrate is formed, and the second slit is formed from one end portion of the film substrate to another end portion of the film substrate in a direction orthogonal to a direction in which the plurality of lead wiring lines extend toward the display region so that the second slit intersects the plurality of lead wiring lines in plan view.

### Fifth Aspect

The display device according to the fourth aspect, wherein in the frame region, a plurality of inorganic film layers are provided between the resin layer and the plurality of lead wiring lines, in the plurality of inorganic film layers, a third slit being formed by removing at least a part of thickness of the plurality of inorganic film layers is formed, and the third slit is formed in at least a part of the plurality of inorganic film layers overlapping the second slit so that the third slit intersects the plurality of lead wiring lines.

### Sixth Aspect

The display device according to any one of the first to fifth aspects, wherein in the frame region, at least one of an element and a wiring line is provided so as to overlap the first slit.

### Seventh Aspect

The display device according to the sixth aspect, wherein a first metal layer, an inorganic film layer, and a second metal layer are sequentially formed on the another surface of the resin layer in mentioned order, the element is a plurality of inspection transistors, the wiring line is a plurality of inspection wiring lines, the plurality of lead wiring lines, and the plurality of external signal input wiring lines, each of the plurality of inspection wiring lines is formed using the first metal layer, the plurality of external signal input wiring lines and the plurality of lead wiring lines are formed using the second metal layer, a signal input from one of the plurality of inspection wiring lines is output from at least a part of the plurality of lead wiring lines via a corresponding one of the plurality of inspection transistors, and the plurality of inspection transistors, a part of the plurality of lead wiring lines, a part of the plurality of inspection wiring lines, and a part of the plurality of external signal input wiring lines overlap the first slit.

### Eighth Aspect

The display device according to any one of the first to seventh aspects, wherein the driving chip is a source driver, a gate driver is provided on the another surface of the resin layer, and the plurality of external signal input wiring lines overlapping the first slit includes a wiring line used to input an external signal to the gate driver.

### Ninth Aspect

The display device according to the eighth aspect, wherein a plurality of transistors are provided in each of the display region and the gate driver, and the plurality of transistors provided in the display region and the plurality of transistors provided in the gate driver are formed using a same material.

### Tenth Aspect

The display device according to any one of the first to ninth aspects, wherein the first slit is one slit having an island shape being formed by removing thickness of the adhesive layer and the thickness of the film substrate.

### Eleventh Aspect

The display device according to the first aspect, wherein the first slit is one slit having an island shape being formed by removing the thickness of the film substrate.

### Twelfth Aspect

The display device according to any one of the first to ninth aspects, wherein the first slit is a plurality of slits each having an island shape being formed by removing thickness of the adhesive layer and the thickness of the film substrate.

### Thirteenth Aspect

The display device according to any one of the first to ninth aspects, wherein the first slit is a plurality of slits each having an island shape being formed by removing a part of thickness of the adhesive layer and the thickness of the film substrate.

### Fourteenth Aspect

The display device according to the first aspect, wherein the first slit is a plurality of slits each having an island shape being formed by removing the thickness of the film substrate.

### Fifteenth Aspect

The display device according to any one of the first to ninth aspects, wherein the first slit is one slit having an island shape being formed by removing a part of thickness of the adhesive layer and the thickness of the film substrate.

### Additional Items

The present invention is not limited to each of the embodiments described above, and various modifications may be made within the scope of the claims. Embodiments obtained by appropriately combining technical approaches disclosed in each of the different embodiments also fall within the technical scope of the present invention.

Moreover, novel technical features can be formed by combining the technical approaches disclosed in the embodiments.

### INDUSTRIAL APPLICABILITY

The present invention can be utilized for a display device.

### REFERENCE SIGNS LIST

1, 1a, 1b, 1c Flexible organic EL display device
3 Barrier layer
4 TFT layer
5 Organic EL element layer
6 Sealing layer
7 Inorganic layered film
10 Film substrate
11 Adhesive layer
12 Resin layer
16, 18, 20 Inorganic insulating film
21 Flattening film
30R, 30L Gate driver
31 Driving chip
32 Anisotropic conductive material
SL1 to SL4 First slit
CL Second slit
CL′ Bending slit (third slit)
DA Display region
NA Frame region
TM1 to TMm External signal input wiring line
TW1 to TWn Lead wiring line
31IBm Input terminal
31OBn Output terminal
Tr Thin film transistor
GE Gate electrode
SH Source-drain wiring line
CE Capacitance electrode
KTR Inspection transistor group
KTRIk Inspection wiring line

1. A display device comprising:
a resin layer;
a film substrate bonded to one surface of the resin layer by using an adhesive layer;
a display region provided on another surface of the resin layer opposite to the one surface of the resin layer; and
a frame region provided around the display region,
wherein, in the frame region, a plurality of external signal input wiring lines, a driving chip including a plurality of input terminals and a plurality of output terminals, and a plurality of lead wiring lines extending from the display region are provided,
each of the plurality of input terminals of the driving chip is disposed on a corresponding one of the plurality of external signal input wiring lines and is electrically connected to the corresponding one of the plurality of external signal input wiring lines by using an anisotropic conductive material,
each of the plurality of output terminals of the driving chip is disposed on a corresponding one of the plurality of lead wiring lines and is electrically connected to the corresponding one of the plurality of lead wiring lines by using the anisotropic conductive material,
in the film substrate, a first slit being formed by removing thickness of the film substrate is formed, and
in the film substrate, the first slit is formed in at least a part of a region overlapping a region between the plurality of input terminals of the driving chip and the plurality of output terminals of the driving chip.

2. The display device according to claim 1,
wherein in the adhesive layer and the film substrate, the first slit is formed by removing at least a part of thickness of the adhesive layer and the thickness of the film substrate, and
the first slit is formed in the adhesive layer and the film substrate in at least a part of a region overlapping a region between the plurality of input terminals of the driving chip and the plurality of output terminals of the driving chip.

3. The display device according to claim 1,
wherein in the film substrate, the first slit is formed between inside of one end portion and inside of another end portion in a direction orthogonal to a direction in which the plurality of lead wiring lines extend toward the display region.

4. The display device according to claim 1,
wherein at least in the film substrate of the adhesive layer and the film substrate, a second slit being formed by removing at least a part of the thickness of the film substrate is formed, and
the second slit is formed from one end portion of the film substrate to another end portion of the film substrate in a direction orthogonal to a direction in which the plurality of lead wiring lines extend toward the display region so that the second slit intersects the plurality of lead wiring lines in plan view.

5. The display device according to claim 4,
wherein in the frame region, a plurality of inorganic film layers are provided between the resin layer and the plurality of lead wiring lines,
in the plurality of inorganic film layers, a third slit being formed by removing at least a part of thickness of the plurality of inorganic film layers is formed, and
the third slit is formed in at least a part of the plurality of inorganic film layers overlapping the second slit so that the third slit intersects the plurality of lead wiring lines.

6. The display device according to claim 1,
wherein in the frame region, at least one of an element and a wiring line is provided so as to overlap the first slit.

7. The display device according to claim 6,
wherein a first metal layer, an inorganic film layer, and a second metal layer are sequentially formed on the another surface of the resin layer in mentioned order,
the element is a plurality of inspection transistors,
the wiring line is a plurality of inspection wiring lines, the plurality of lead wiring lines, and the plurality of external signal input wiring lines,
each of the plurality of inspection wiring lines is formed using the first metal layer,
the plurality of external signal input wiring lines and the plurality of lead wiring lines are formed using the second metal layer,
a signal input from one of the plurality of inspection wiring lines is output from at least a part of the plurality of lead wiring lines via a corresponding one of the plurality of inspection transistors, and
the plurality of inspection transistors, a part of the plurality of lead wiring lines, a part of the plurality of inspection wiring lines, and a part of the plurality of external signal input wiring lines overlap the first slit.

8. The display device according to claim 1,
wherein the driving chip is a source driver,
a gate driver is provided on the another surface of the resin layer, and
the plurality of external signal input wiring lines overlapping the first slit includes a wiring line used to input an external signal to the gate driver.

9. The display device according to claim 8,
wherein a plurality of transistors are provided in each of the display region and the gate driver, and
the plurality of transistors provided in the display region and the plurality of transistors provided in the gate driver are formed using a same material.

10. The display device according to claim 1,
wherein the first slit is one slit having an island shape being formed by removing thickness of the adhesive layer and the thickness of the film substrate.

11. The display device according to claim 1,
wherein the first slit is one slit having an island shape being formed by removing the thickness of the film substrate.

12. The display device according to claim 1,
wherein the first slit is a plurality of slits each having an island shape being formed by removing thickness of the adhesive layer and the thickness of the film substrate.

13. The display device according to claim 1,
wherein the first slit is a plurality of slits each having an island shape being formed by removing a part of thickness of the adhesive layer and the thickness of the film substrate.

14. The display device according to claim 1,
wherein the first slit is a plurality of slits each having an island shape being formed by removing the thickness of the film substrate.

15. The display device according to claim 1,
wherein the first slit is one slit having an island shape being formed by removing a part of thickness of the adhesive layer and the thickness of the film substrate.
